(19) United States
(12) Patent Application Publication
(10) Pub. No.: US 2012/0068044 A1
(43) Pub. Date: Mar. 22, 2012

(54) HANDS FREE MEDIA PLATFORM

(76) Inventor: LOUIS ANGEL RIVERA, Newbury Park, CA (US)

(21) Appl. No.: 13/232,834

(22) Filed: Sep. 14, 2011

Related U.S. Application Data
(60) Provisional application No. 61/384,654, filed on Sep. 20, 2010.

(51) Int. Cl. H05K 7/00; F16M 13/00

(52) U.S. Cl. 248/682; 248/295.11; 248/286.1; 248/291.1; 248/284.1

(57) ABSTRACT

A hands free media platform apparatus is disclosed. The media platform may include a collar, a pair or arms projecting from the collar, and a platform coupled to the arms. The platform is adapted to hold media so that the media is viewable by a user wearing the apparatus without the media being hand held. The apparatus may include adjustable elements providing customized viewing angles of media carried on the platform.

### CROSS-REFERENCE TO RELATED APPLICATION

This application claims the benefit of priority of U.S. provisional patent application No. 61/384,654, filed, Sep. 20, 2010, the contents of which are herein incorporated by reference.

### BACKGROUND OF THE INVENTION

The present invention generally relates to media accessories, and more particularly, to a hands free media platform.

Individuals may at times require extended viewing of an object. For example, a person viewing a handheld electronic device such as a smart phone or electronic tablet may need to hold the device for several minutes. The device may begin to feel heavy after a while causing fatigue and strain on the person's hands. Even non-electronic media may be cumbersome to hold during extended periods.

As can be seen, there is a need for an apparatus that allows a user to carry a media device without using one's hands.

### SUMMARY OF THE INVENTION

In one aspect of the present invention, a hands free media platform apparatus comprises a collar; a pair of telescoping arms attached to the collar; and a platform coupled to the pair of telescoping arms.

In another aspect of the present invention, a hands free media platform apparatus comprises a collar; a pair of arms projecting downward from ends of the collar; and a platform coupled to the pair or arms wherein the platform is disposed to pivot on the arms to face a user wearing the apparatus.

These and other features, aspects and advantages of the present invention will become better understood with reference to the following drawings, description and claims.

### BRIEF DESCRIPTION OF THE DRAWINGS

FIG. 1 is a perspective view of a hands free media platform shown in use according to an exemplary embodiment of the present invention;

FIG. 2 is a perspective view of the hands free media platform of FIG. 1 in a partially extended position;

FIG. 3 is a side view of the hands free media platform of FIG. 1 in a partially extended position;

FIG. 4 is a perspective view of the hands free media platform of FIG. 1 illustrating range of motion of multiple component;

FIG. 5 is a perspective view of the hands free media platform of FIG. 1 illustrated in a folded configuration;

FIG. 6 is a perspective view of the hands free media platform of FIG. 1 shown in use and illustrated in a folded configuration;

FIG. 7 is a perspective view of the hands free media platform of FIG. 1 with a lanyard attached according to another exemplary embodiment of the present invention;

FIG. 8 is a cross section view of the hands free media platform taken along the line 8-8 of FIG. 5; and

FIG. 9 is a top view of an exemplary platform used in the hands free media platform of FIG. 1.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims. Various inventive features are described below that can each be used independently of one another or in combination with other features.

Broadly, embodiments of the present invention generally provide a media platform apparatus that allows a user to carry and view media without the use of hands. Aspects of the apparatus disclosed provide adjustability to the viewing angle of media held on the apparatus. Other aspects provide a lightweight feel to mitigate fatigue. Still yet, other aspects provide adaptability to various sized media being carried on the apparatus.

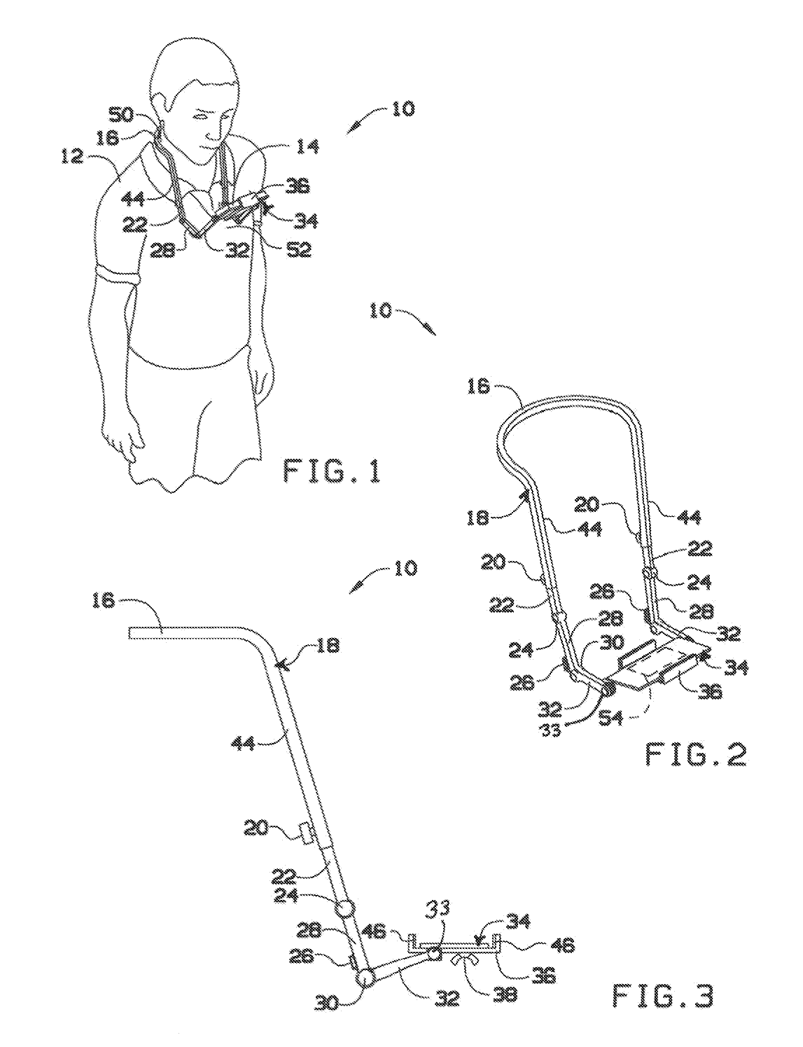

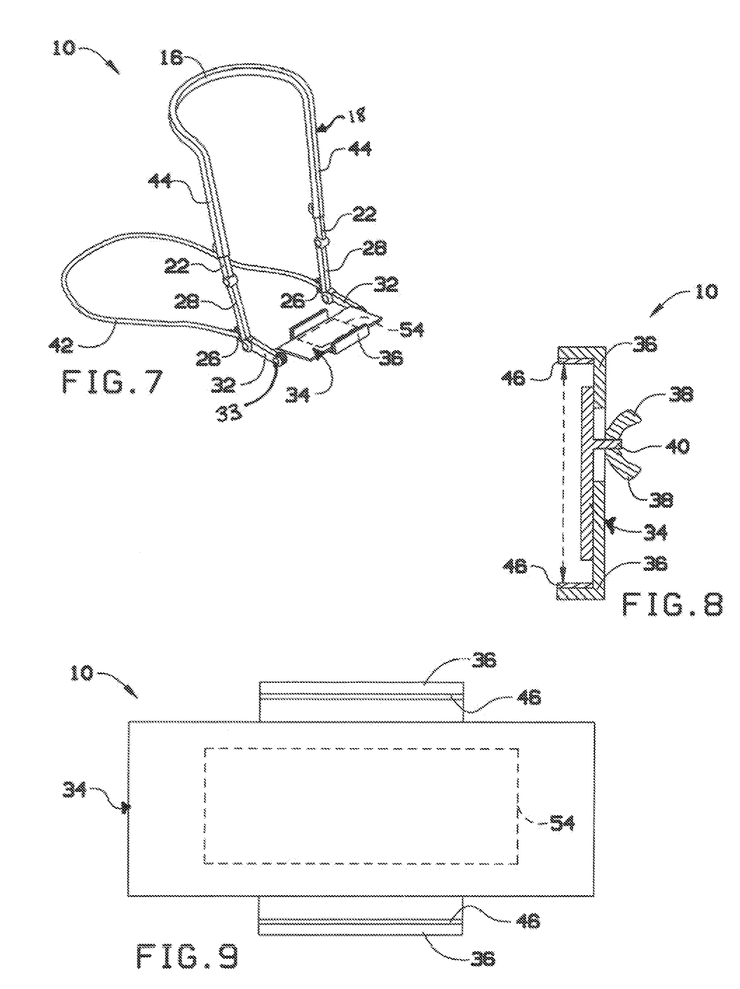

Referring now to FIGS. 1-7, a hands free media platform apparatus 10 (also referred to generally as the apparatus 10) is shown according to an exemplary embodiment of the present invention. The apparatus 10 includes a collar 16, a pair of arms 18, and a platform 34. Aspects of the apparatus 10 may be configured to provide comfortable viewing of a media device 54 from the platform 34. For sake of illustration, no one particular media device is shown, however approximate positioning of the media device 54 (unclamped) on the platform 34 is shown by way of dashed lines.

The collar 16 and the arms 18 may be made of lightweight rigid material, for example, plastic or titanium. The collar 16 and arms 18 may be hollow. The collar 16 may be rounded and adapted to fit comfortably around a neck 50 of a user 12. Ends of the collar 16 may be coupled to the arms 18. In one exemplary embodiment, the arms 18 may project downwardly from the collar ends at a range of angles from approximately 0 degrees to 180 degrees from a plane of the collar 16.

The arms 18 may position the platform 34 in front of a user's chest 52. The arms 18 may be telescopic. In exemplary embodiments including the telescopic feature, each of the arms 18 may include an upper arm portion 44 and a lower arm portion 22. The lower arm portion 22 may telescope adjustably from the upper arm portion 44 via an adjuster 20, which may be a tension knob. The lower arm portion 22 may be pivotable to provide an improved viewing angle of the media device 54. The lower arm portion 22 may include a first segment 28 and a second segment 32. A pivot 24 on the lower arm portion 22 may be positioned intermediately of the upper arm portion 44 and the first segment 28. Another pivot 30 may be positioned at a junction of the first segment 28 and the second segment 32. A lanyard clip 26 may be attached to the first segment 28 for attachment of a lanyard 42.

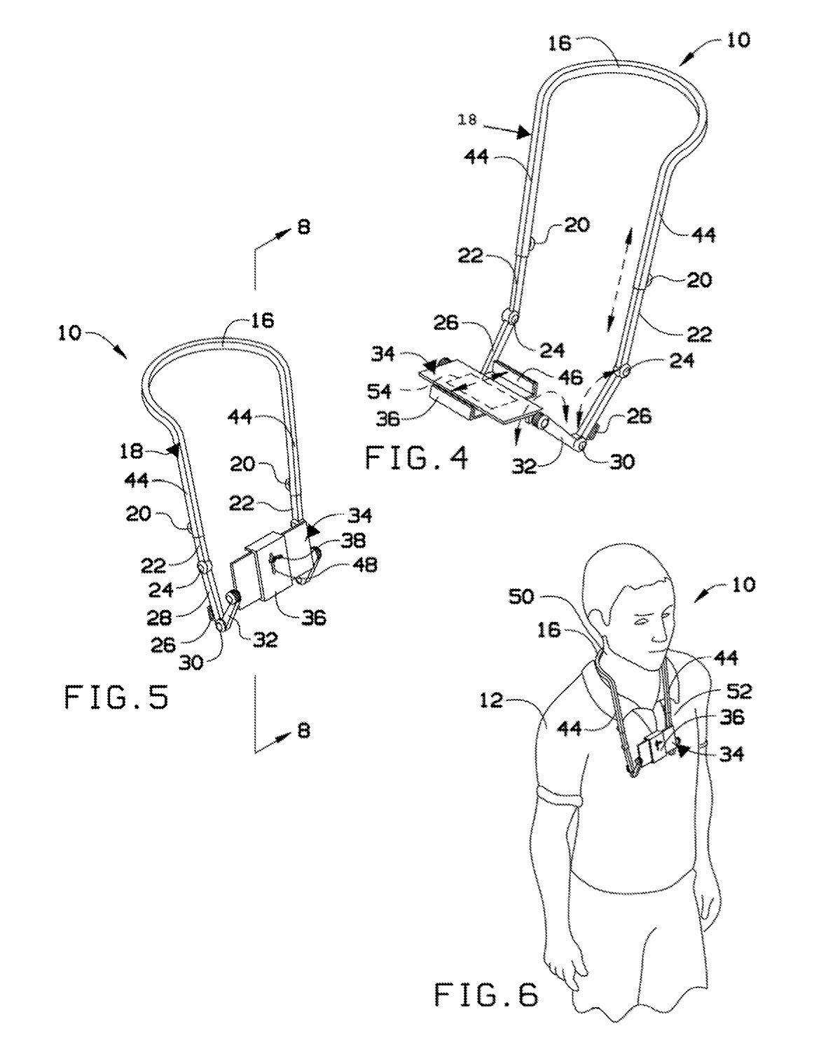

Referring now to FIGS. 4-9, still further convenience may be provided by adjustability of the platform 34. The platform 34 may be rotationally adjustable about a pivot 33 connecting the second segment 32 to the platform 34. The platform 34 may be configured to rotate in a range of 0 degrees to 90 degrees around the pivot 33. The platform 34 may also include a clamp 36 that is configured to slide inward and outward to accommodate a tight fit around a perimeter of the media device 54. A cushion pad 46, such as rubber may protect the media device 54 from the clamp 36 and provide traction so to prevent the media device 54 from slipping off the platform 34. The breadth of detention by the clamp 36 may be controlled by a wing nut 38 and screw 40 combination that lock the screw 40 into place along the length of a slot 48 disposed on the clamp 36.

In an exemplary operation, the user 12 may slide the collar 16 around the neck 50. The lightweight collar 16 and arms 18 may provide extended use by mitigating weight and strain on the neck 50. The media device 54 may be clamped into position on the platform 34. The user 12 may adjust the length of the arms 18 and pivot, for example, the lower arm portion 22 until the media device 54 is at a desirable viewing distance. The platform 34 may then be rotated about pivot 33 until the user 12 is comfortable with a viewing angle of the media device 54. Thus, the user 12 may enjoy viewing of the media device 54 for extended periods with the weight of the media device 54 supported by the neck 50. The lanyard 42 may carry the apparatus 10 when it is not in use. Referring to FIG. 6, upon completion of viewing, the platform 34, while holding the media device 54, may be rotated and folded inward until the media device 54 faces the user 12.

While the foregoing was shown with a platform 34 configured to hold a media device in a substantially parallel orientation to the user 12 body, it will be understood that other embodiments may configure the platform 34 to swivel axially and orient the media device 54 into a substantially perpendicular orientation to the user 12 body.

It should be understood, of course, that the foregoing relates to exemplary embodiments of the invention and that modifications may be made without departing from the spirit and scope of the invention as set forth in the following claims.

What is claimed is:

1. A hands free media platform apparatus, comprising:
a collar;
a pair of telescoping arms attached to the collar; and
a platform coupled to the pair of telescoping arms.

2. The hands free media platform apparatus of claim 1, wherein the platform is pivotable on the telescopic arms.

3. The hands free media platform apparatus of claim 2 further comprising a clamp coupled to the platform, the clamp adapted to secure an article of media onto the platform.

4. The hands free media platform apparatus of claim 2, wherein the telescoping arms are made from plastic or titanium.

5. The hands free media platform apparatus of claim 1 further comprising a lanyard coupled to the telescoping arms.

6. The hands free media platform apparatus of claim 1, wherein the collar is rigid.

7. The hands free media platform apparatus of claim 1, wherein the collar and the telescoping arms are hollow.

8. A hands free media platform apparatus, comprising:
a collar;
a pair of arms projecting downward from ends of the collar; and
a platform coupled to the pair or arms wherein the platform is disposed to pivot on the arms to face a user wearing the apparatus.

9. The hands free media platform apparatus of claim 8, wherein the arms are configured to telescope.

10. The hands free media platform apparatus of claim 8, wherein the arms are configured to pivot.
